(19) United States
(12) Patent Application Publication
(10) Pub. No.: US 2009/0239326 A1
(43) Pub. Date: Sep. 24, 2009

(54) METHOD FOR MANUFACTURING MICROCRYSTALLINE SILICON SOLAR CELL

(76) Inventor: Seung-Yeop Myong, Seoul (KR)

Correspondence Address: The Belles Group, P.C., 1518 Walnut Street, Suite 1706, Philadephia, PA, 19102, US

(21) Appl. No.: 12/407,114

(22) Filed: Mar. 19, 2009

(30) Foreign Application Priority Data
Mar. 19, 2008 (KR) 10-2008-0025433

(51) Int. Cl. H01L 31/0264

(52) U.S. Cl. 438/57; 257/E31.004

(57) ABSTRACT

A method for manufacturing a microcrystalline silicon solar cell comprises forming a zinc oxide transparent electrode with a textured surface on an insulation substrate by chemical vapor deposition, etching the zinc oxide transparent electrode with acid water solution and depositing a microcrystalline silicon thin film on the zinc oxide transparent electrode with the textured surface.

This application claims the benefit of Korean Patent Application No. 10-2008-0025433 filed on Mar. 19, 2008, which is hereby incorporated by reference.

### BACKGROUND

1. Field

The present invention relates to a method for manufacturing a microcrystalline silicon solar cell.

2. Description of the Related Art

Microcrystalline silicon solar cells have lower light-induced degradation compared to amorphous silicon solar cells. Further, the microcrystalline silicon solar cells have an absorber with an optical band gap about 1.1 eV, which is less than 1.75 eV for a light absorber of the amorphous silicon solar cells. For this reason, it is advantageous that the microcrystalline silicon solar cells may absorb near infrared light as well as visible light.

However, because the microcrystalline silicon solar cells have small absorption coefficient, they need the thickness of about 50 μm to sufficiently absorb the visible light and the near infrared light. If the microcrystalline silicon solar cells have the thickness of about 50 μm, a short-circuit current increases. However, a deposition time is long, an open-circuit voltage is reduced, and a fill factor (FF) is deteriorated, that leads to a reduction in overall efficiency.

Accordingly, in order to manufacture high efficiency thin microcrystalline silicon solar cells, a significantly important consideration is to maximize light trapping effect.

Light scattering due to surface texture of a transparent front electrode is important for the transparent front electrode to improve the path length for incident light in the light absorber. Further, there is a demand for the durability against hydrogen plasma to form a microcrystalline silicon thin film. For this reason, a transparent electrode made of zinc oxide (ZnO) has been widely used.

In this case, since the zinc oxide (ZnO) may be used to form a transparent conducting oxide (TCO) and an emitter of a thin film solar cell, a thin film transistor liquid crystal display (TFT LCD), and a photo device such as an organic electro luminescence (OEL) device, a blue light emitting diode (LED) and a laser diode (LD), and have a nano-structure such as nano-quantum dot array, nano-rod, or nano-belt, it is recently attracting attention.

Meanwhile, CVD such as metal-organic chemical vapor deposition (MOCVD) or low pressure chemical vapor deposition (LPCVD), or a sputtering method have been widely used to form a zinc oxide transparent electrode for a thin film silicon solar cell. So as to improve electrical conductivity of the zinc oxide transparent electrode, n-type impurity such as boron (B), aluminum (Al), or gallium (Ga) is added. In a case of zinc oxide (ZnO) deposited by sputtering, although electrical conductivity and its stability in air are excellent, a deposition rate is low, large area uniformity is deteriorated, large area manufacturing cost is expensive, and there is no distinct surface texture.

FIG. 1 is a cross-sectional view illustrating a microcrystalline silicon formed along an textured portion of a zinc oxide thin film according to the prior art.

Referring to FIG. 1, in the microcrystalline silicon solar cell according to the prior art, a transparent electrode 2 is deposited on a substrate 1 by chemical vapor deposition (CVD) method. Accordingly, the transparent electrode has a pyramidal textured surface 3 with a V-shaped valley shape. The microcrystalline silicon solar cell according to the prior art includes a p-type microcrystalline silicon (p-μc-Si:H) window layer (not shown) and an intrinsic microcrystalline silicon (i-μc-Si:H) light absorber 6 formed on the transparent electrode 2.

In a case of zinc oxide (ZnO) deposited by the CVD, a deposition rate is high. Further, upon deposition on a large area, since the zinc oxide has excellent uniformity and a naturally textured surface 3 is formed to have a pyramid shape of 100 nm˜500 nm size, and manufacturing cost is low, it is beneficial in mass production.

The pyramidal textured surface 3 is very effective in efficiency improvement of an amorphous silicon solar cell, but leads to the following problems in the microcrystalline silicon solar cell.

The pyramidal textured surface 3 has a V-shaped valley shape. Upon formation of a microcrystalline silicon thin film, the textured surface 3 having the V-shaped valley shape acts like crack to inhibit formation of a microcrystal, to form an amorphous incubation layer 4 and a grain boundary 5 with a large volume. The incubation layer 4 and the grain boundary 5 increase the recombination of photogenerated electron-hole pairs in the microcrystalline silicon solar cell to deteriorate overall performance.

Meanwhile, a sharply pyramidal textured surface limits a grain size of a microcrystalline silicon. Accordingly, although a crystal volume fraction is high, a microcrystalline silicon with a small grain size is formed. In a case of a microcrystalline silicon thin film with a small grain size, a volume of the grain boundary is relatively large to recombine the photogenerated electron-hole pair easily. Accordingly, the microcrystalline solar cell with a small grain size has low efficiency.

There has been proposed a research transforming a pyramidal textured surface into a crator-like textured surface with a gentle U-shaped valley shape through plasma processing in order to solve disadvantages of the zinc oxide transparent electrode deposited by the CVD (Bailat J., Proc. of The 4th WCPEC, Hawaii, 2006, p. 1533) in the microcrystalline silicon solar cell.

There has been proposed a p-i-n type high-efficiency microcrystalline solar cell of 9.9% capable of improving an open voltage and a fill factor of the microcrystalline silicon solar cell through such transformation of the textured surface. However, because it takes longer than 120 minutes in a case of plasma processing, it is not suitable for mass production.

### SUMMARY

In one embodiment, a method for manufacturing a microcrystalline silicon solar cell comprises forming a zinc oxide transparent electrode with a textured surface on an insulation substrate by chemical vapor deposition, etching the zinc oxide transparent electrode with acid water solution and depositing a microcrystalline silicon thin film on the zinc oxide transparent electrode with the textured surface.

The method further comprises may dry-clean or wet-clean the substrate after step after etching.

The zinc oxide transparent electrode may have a thickness ranging from 2 μm to 2.5 μm.

The acid water solution may have a concentration ranging from 0.5% to 5%.

The acid water solution may contain at least one of hydrochloric acid (HCl), phosphoric acid (HPO₃), nitric acid (HNO₃), and acetic acid (CH₃COOH).

The substrate on which the transparent electrode is formed may be put in the acid water solution for 5 seconds to 20 seconds.

The textured surface may have a V-shaped valley shape.

### BRIEF DESCRIPTION OF THE DRAWINGS

The accompany drawings, which are included to provide a further understanding of the invention and are incorporated on and constitute a part of this specification, illustrate embodiments of the invention and together with the description serve to explain the principles of the invention. In the drawings:

FIG. 1 is a cross-sectional view illustrating a microcrystalline silicon formed along a texture portion of a zinc oxide thin film according to a prior art.

FIG. 2 is a cross-sectional view illustrating a microcrystalline silicon formed along a texture of a zinc oxide thin film in accordance with an embodiment of the present invention.

FIG. 3 is a flow chart illustrating a method for manufacturing a microcrystalline silicon solar cell in accordance with an embodiment of the present invention.

### DETAILED DESCRIPTION OF EMBODIMENTS

Reference will now be made in detail embodiments of which are illustrated in the accompanying drawings.

A microcrystalline silicon thin film in accordance with the present embodiment includes a front electrode 20 coated on a substrate 10 by chemical vapor deposition (CVD). As described above, when the front electrode 20 is formed by the CVD, the front electrode 20 has a sharply pyramidal textured surface.

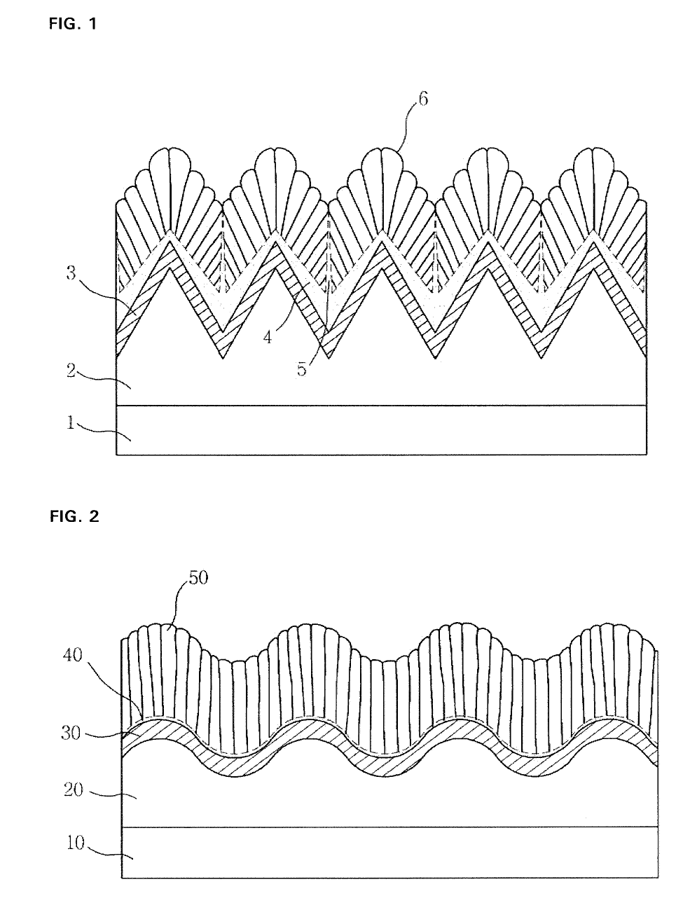

Referring to FIG. 2, in an embodiment of the present invention, a pyramidal textured surface becomes gentle within a short time through chemical etching. Namely, a pyramidal textured surface 20 of zinc oxide shown in FIG. 1 is transformed into a gentle crator-like surface with U-shaped valley shape in a short time by chemical etching. Since the front electrode is modified to have a gentle textured surface, a high efficiency microcrystalline silicon solar cell with p-type layer-i-type layer-n-type layer may be manufactured.

In a case of a thin film solar cell, the substrate 10 is a part to which light is primarily incident. The substrate 10 has excellent light transmission, and my be made of transparent insulation materials in order to prevent internal short-circuit in the thin film solar cell.

Meanwhile, in a case of a device such as thin film transistor liquid crystal display (TFT LCD), organic electro luminescence (CEL) device, or blue light emitting diode (LED), the substrate 10 may be made of transparent insulation materials so that light generated inside the device through a substrate 10 is emitted to an outside, and internal short-circuit in the device is prevented.

For example, one selected from the group consisting of a soda lime glass, a low iron glass, a normal glass, and a tempered glass may be as a material of the substrate 10. Polymer material substrate may be used as the substrate 10. Besides this, a silicon substrate or a sapphire substrate can be also used as the substrate 10. The present invention is not limited to the foregoing listed materials.

Since light scattering through a textured surface 30 of a transparent front electrode 20 to which light is incident is important, and the durability against hydrogen plasma is required to form a microcrystalline silicon thin film, a transparent electrode made of zinc oxide (ZnO) is used.

In the present embodiment, after deposition of the transparent front electrode 20, a sharply textured surface of the transparent front electrode 20 is transformed into a gentle textured surface through chemical etching using acid water solution with predetermined concentration such as hydrochloric acid water solution.

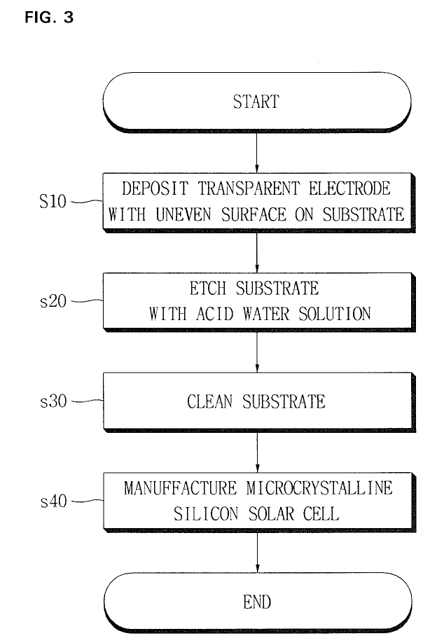

Hereinafter, a method for manufacturing a microcrystalline silicon solar cell with a microcrystalline silicon thin film having a structure as described above will be explained in detail. Referring to FIG. 2 and FIG. 3, a transparent front electrode 20 with a sharply pyramid shape is deposited on the substrate 10 by CVD to have a thickness ranging from 2 μm to 2.5 μm (S10). In this case, the transparent front electrode 20 may comprise zinc oxide and the zinc oxide may be doped by impurities.

The zinc oxide transparent front electrode 20 may have resistivity of about 1×10⁻³ Ωcm, hall mobility of about 30 cm²/Vs, and average total transmittance greater than 80% in a visible light region.

Referring to FIG. 3, when a substrate on which a transparent front electrode is deposited is put in acid water solution of a concentration ranging from 0.5% to 5% for 5 seconds to 20 seconds (S20), a surface of the transparent front electrode 20 is etched to transform a sharply pyramid-shaped texture surface 30 into a gentle crater-like texture surface 30.

If the concentration of acid water solution is less than 0.5%, because the etching rate is too low, it takes a long time to etch the surface of the front electrode 20. If the concentration of acid water solution is greater than 5%, the etching rate is too high so that it is difficult to control an etching process. Accordingly, in the latter case, the surface morphology of zinc oxide becomes non-uniform. Namely, if the concentration of the acid water solution ranges from 0.5% to 5%, etching is controllable and is achieved sufficiently.

Further, if an etching time of the surface of the front electrode 20 in the acid water solution is less than 5 seconds, sufficient etching cannot be achieved. If the etching time of the surface of the front electrode 20 in the acid water solution is greater than 20 seconds, a surface texture becomes too smooth to maintain light trapping effect. Accordingly, a short-circuit current is reduced or zinc oxide is too thin to maintain conductivity and fill factor, with the result that conversion efficiency can be reduced. If the etching time of the surface of the front electrode 20 in the acid water solution ranges from 5 seconds to 20 seconds, a gentle texture surface is formed within a short time not to reduce light trapping effect and a short-circuit current and to prevent reduction of conversion efficiency due to reduction originated from the decrease in the electrical conductivity and fill factor.

The acid water solution may comprise at least one of hydrochloric acid (HCl), phosphoric acid (HPO₃), nitric acid (HNO₃), or acetic acid (CH₃COOH).

Meanwhile, due to etching, transmittance may be increased but electrical conductivity may be reduced. However, the etching is performed for a short time ranging from 5 seconds to 20 seconds, electrical characteristics or optical characteristics can be maintained without significant change in the thickness.

As explained earlier, the shape transformation of a texture surface may improve efficiency due to an enhancement of an open voltage and a fill factor. Furthermore, a crystal volume fraction of the microcrystalline silicon solar cell may be improved from improvement of a grain size of an intrinsic microcrystalline silicon under the same process. That is, in order to obtain a desired value of the crystal volume fraction in a specific thickness, a hydrogen dilution ratio for depositing a microcrystalline silicon thin film can be reduced. Since reduction in the hydrogen dilution ratio improves a deposition rate, it reduces a manufacturing time of the microcrystalline silicon thin film solar cell and a used amount of hydrogen, thereby increasing a production capacity and reducing manufacturing cost.

For example, the crystal volume fraction of 45% is obtained by manufacturing a solar cell including a p-type hydrogenous microcrystalline silicon (p-μc-Si:H) window layer and an intrinsic microcrystalline silicon (i-μc-Si:H) light absorber 6 of 2 μm thickness formed on a zinc oxide transparent front electrode with a pyramidal textured surface deposited to 2.1 μm thickness by CVD.

In the meantime, a zinc oxide transparent front electrode of 2.1 μm thickness is formed on a substrate by the CVD. The zinc oxide transparent front electrode has a pyramidal textured surface 30. The zinc oxide transparent front electrode is etched in 5% acetic acid (CH₃COOH) water solution for 15 seconds, and then the zinc oxide transparent front electrode is cleaned. When a microcrystalline silicon solar cell is manufactured through the same process after etching and cleaning process, formation of an incubation film is reduced and the crystal volume fraction is enhanced to 54%.

After performing a dry cleaning step such as rinse or a wet cleaning step (S30) after chemical etching, the substrate 10 on which the transparent front electrode 20 is formed is loaded on a plasma-enhanced chemical vapor deposition (PECVD) device and a microcrystalline silicon thin film with p-type layer-i-type layer-n-type layer is deposited on a gentle textured surface 30 of the transparent front electrode 20. A rear electrode is formed on the microcrystalline silicon thin film to manufacture the microcrystalline silicon solar cell (S40). The p-type layer may be a silicon layer in which an impurity in the Group III in the Periodic Table is doped, the i-type layer may be an intrinsic silicon layer, and the n-type layer may be a silicon layer in which an impurity the Group VI in the Periodic Table is doped.

In FIG. 2, reference numerals 40 and 50 denote an amorphous incubation film and an intrinsic microcrystalline silicon (i-μc-Si:H) receiving layer, respectively. In the present embodiment, because the textured surface of the front electrode 20 becomes gentle due to etching, the thickness of the incubation film 40 of FIG. 2 is less than that of the incubation film 3 of FIG. 1. A grain boundary 1 having big volume as shown in FIG. 1 does not generate in the intrinsic microcrystalline silicon light absorber 50 of FIG. 2. As a result, the recombination of photogenerated electron-hole pairs in the microcrystalline silicon solar cell is reduced.

As is evident from the above explanation, upon manufacturing the microcrystalline silicon solar cell, after a zinc oxide transparent front electrode suitable for mass production is coated on a substrate by the CVD, a surface is transformed into a crater shape with a U-shaped gentle valley to manufacture the microcrystalline silicon solar cell. Accordingly, an open voltage and fill factor are improved without reduction of a short-circuit current to achieve high efficiency.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art.

What is claimed is:

1. A method for manufacturing a microcrystalline silicon solar cell, comprising the steps of:
forming a zinc oxide transparent electrode with a textured surface on an insulation substrate by chemical vapor deposition;
etching the zinc oxide transparent electrode with acid water solution; and
depositing a microcrystalline silicon thin film on the zinc oxide transparent electrode with the textured surface.

2. The method according to claim 1, further comprising dry-cleaning or wet-cleaning the substrate after step after etching.

3. The method according to claim 1, wherein the zinc oxide transparent electrode has a thickness ranging from 2 μm to 2.5 μm.

4. The method according to claim 1, wherein the acid water solution has a concentration ranging from 0.5% to 5%.

5. The method according to claim 1, wherein the acid water solution contains at least one of hydrochloric acid (HCl), phosphoric acid (HPO₃), nitric acid (HNO₃), and acetic acid (CH₃COOH).

6. The method according to claim 1, wherein the substrate on which the transparent electrode is formed is put in the acid water solution for 5 seconds to 20 seconds.

7. The method according to claim 1, wherein the textured surface has a V-shaped valley shape.
